(19) United States
(12) Patent Application Publication
(10) Pub. No.: US 2017/0219386 A1
(43) Pub. Date: Aug. 3, 2017

(54) SENSOR SYSTEM AND METHOD FOR THE CAPACITIVE DETECTION OF OBSTACLES

(71) Applicants: Thomas WIEST, Ochsenhausen (DE); Martin SCHEIBLE, Blaubeuren (DE); Gerd REIME, Buehl (DE); Manuel KELSCH, Ulm (DE); Dominic CZEMPAS, Karlsruhe (DE)

(72) Inventors: Thomas WIEST, Ochsenhausen (DE); Martin SCHEIBLE, Blaubeuren (DE); Gerd REIME, Buehl (DE); Manuel KELSCH, Ulm (DE); Dominic CZEMPAS, Karlsruhe (DE)

(21) Appl. No.: 15/501,567

(22) PCT Filed: Aug. 10, 2015
(86) PCT No.: PCT/EP2015/068370

§ 371 Date: Feb. 3, 2017

(30) Foreign Application Priority Data
Aug. 15, 2014 (DE) 10 2014 216 247.5

(51) Int. Cl. G01D 5/24; H03K 17/955

(52) U.S. Cl. CPC G01D 5/24; H03K 17/955; H03K 2217/960745; H03K 2217/96075

(57) ABSTRACT

A sensor system for the capacitive detection of obstacles, having a capacitive sensor with conductive elements and a control circuit connected thereto. The control circuit has a bridge circuit, and a first end of the bridge branch is connected to a conductive element of the sensor positioned upstream in the direction of detection and a second end of the bridge branch is connected to a conductive element of the sensor positioned downstream in the direction of detection. A control signal is generated by a control section of the control circuit and the sum of impedances of the bridge circuit connected to the first end of the bridge branch is less than the sum of impedances of the bridge circuit connected to the second end of the bridge branch. An electronic evaluation unit is provided to evaluate a voltage difference between the first and second ends of the bridge branch.

The invention relates to a sensor system for the capacitive detection of obstacles, having a capacitive sensor with at least two conductive elements and a control circuit connected to the conductive elements, wherein the control circuit has a bridge circuit, wherein a first end of the bridge branch is connected to a conductive element of the sensor positioned upstream in the direction of detection and a second end of the bridge branch is connected to a conductive element of the sensor positioned downstream in the direction of detection, wherein a control signal is generated by means of a control section of the control circuit and wherein the sum of the impedances of the bridge circuit which are connected to the first end of the bridge branch is less than the sum of the impedances of the bridge circuit which are connected to the second end of the bridge branch. The invention also relates to a method for the capacitive detection of obstacles.

A switching strip system for the capacitive detection of obstacles is known from U.S. Pat. No. 8,334,623 B2. The embodiment shown there in FIG. 14 has a bridge circuit, wherein the two conductors of a switching strip profile are connected in each case to one end of the bridge branch. However, the switching strip system is evaluated by comparing a voltage on the conductor located downstream in the direction of detection with a reference signal unaffected by a change in the capacitance between the two conductors and an obstacle.

A switching strip system for the capacitive detection of obstacles is known from U.S. Pat. No. 6,750,624, in which a switching strip profile is provided with at least one conductor running continuously in the longitudinal direction, a central electronic unit, a front-end electronic unit and a transmission line between the central electronic unit and the front-end electronic unit. The front-end electronic unit has an oscillator to generate a control signal at a high frequency of around 900 MHz and transmit it to the at least one electrical conductor in the switching strip profile. A comparison circuit for comparing the signal present on the conductor of the switching profile and the uninfluenced control signal is similarly provided in the front-end electronic unit. An output signal of the front-end electronic unit is transmitted via the transmission line to the central electronic unit. The transmission line is designed as a coaxial cable or a twisted-pair line.

A sensor system and a method for the capacitive detection of obstacles are intended to be improved with the invention, particularly in terms of sensitivity to electromagnetic interference and temperature fluctuations.

According to the invention, a sensor system for the capacitive detection of obstacles is provided, having a capacitive sensor with at least two conductive elements and a control circuit connected to the conductive elements, wherein the control circuit has a bridge circuit, wherein a first end of the bridge branch is connected to a conductive element of the sensor positioned upstream in the direction of detection and a second end of the bridge branch is connected to a conductive element of the sensor positioned downstream in the direction of detection, wherein a control signal is generated by means of a control section of the control circuit and wherein the sum of the impedances of the bridge circuit which are connected to the first end of the bridge branch is less than the sum of the impedances of the bridge circuit which are connected to the second end of the bridge branch, wherein an electronic evaluation unit is provided to evaluate a voltage difference between the first end and the second end of the bridge branch.

Given that a voltage difference between the first end and the second end of the bridge branch is evaluated according to the invention, interfering influences on the signal of the two electrodes have no influence on the evaluation of the voltage difference, since interfering influences normally affect both electrodes or all electrodes of the sensor and are thereby eliminated in the evaluation of the voltage difference between the first end and the second end of the bridge branch. This applies, for example, to signal changes due to the temperature behavior of the control circuit and of the switching strip profile itself. The temperature differences between the at least two conductive elements of the sensor can be ignored, so that temperature-dependent components of the bridge voltage are automatically eliminated in the evaluation of the voltage difference. The same applies if electromagnetic interference is present. Both or all conductors of the switching strip profile are essentially influenced in the same way by electromagnetic interference, so that these interfering influences are also automatically eliminated in the evaluation of the voltage difference between the first end and the second end of the bridge branch.

As a result, the sensor system according to the invention is extremely insensitive to interfering influences and is particularly suitable for use in motor vehicles, for example to protect electromotively operated tailgates, windows and doors. The invention is based on the surprising finding that the fundamental disadvantage in evaluating a voltage difference between two conductive elements of the sensor and specifically between the first end and the second end of a bridge branch is more than compensated by the advantages in terms of insensitivity to interfering influences, in particular temperature influences and EMC interference. In a sensor system for the capacitive detection of obstacles, both the conductive element of the sensor positioned upstream in the direction of detection and the conductive element of the sensor positioned downstream in the direction of detection form a capacitance with the obstacle and these two capacitances change as an obstacle approaches. Unlike the comparison of the signal of only one conductive element with an unchanged reference signal, the determination of the difference between the signals of the two elements therefore has the disadvantage that the differential signal is less than in a circuit with an uninfluenced reference path, as shown, for example, in U.S. Pat. No. 8,334,623 B2, FIG. 14. Specifically, in the solution according to the invention, the disadvantage occurs that the voltage deviation which occurs as an obstacle approaches the two electrodes of the sensor is compensated to some extent by the determination of the voltage difference from the voltages which are present on the two electrodes. However, the solution according to the invention offers substantial advantages in terms of EMC and temperature behavior. The difference determination or the evaluation of the voltage difference between the first end and the second end of the bridge branch results in a very low-noise signal which can be very highly amplified. Due to the improved signal-to-noise ratio of this voltage differential signal compared with circuits corresponding to the prior art, significantly smaller changes in the voltage differential signal can surprisingly be evaluated, so that the fundamental disadvantage is compensated and a considerable insensitivity to interfering influences can simultaneously be achieved. The control signal is fed into both electrodes or all electrodes of the switching strip profile. The field radiated by the electrode positioned upstream in the direction of detection is then provided to align to some extent the field radiated by the electrode positioned downstream in the direction of detection. The conductive elements or electrodes of the sensor can be designed as conductors running continuously in the longitudinal direction of a switching strip profile or as flat electrodes, for example foil electrodes or grid electrodes of a capacitive area sensor.

In one development of the invention, the control section has a first impedance, wherein the first end of the bridge branch is disposed between a second and a third impedance and the second end of the bridge branch is disposed between a fourth and a fifth impedance, wherein the first impedance is less than the sum of the second and the third impedance and the sum of the second and the third impedance is less than the sum of the fourth and the fifth impedance.

As a result, the control section has a lower-impedance connection compared with the bridge branches. Since the conductor of the switching strip profile positioned upstream in the direction of detection has a higher-impedance connection than the control section, but a lower-impedance connection than the conductor of the switching strip profile positioned downstream in the direction of detection, the signal on the conductor positioned downstream in the direction of detection changes more substantially than the signal positioned upstream as seen in the direction of detection as an obstacle approaches the switching strip profile. The approach of an obstacle to the switching strip profile thus causes a voltage difference between the two conductors or between the first end and the second end of the bridge branch which can then be evaluated. For example, the impedances are selected so that the sum of the impedances Z₄ and Z₅ is greater than or equal to five times the sum of the impedances Z₂ and Z₃.

In one development of the invention, an adjustable impedance is provided in parallel with at least one of the impedances of the bridge circuit in order to effect an equalization of the voltage difference between the first end and the second end of the bridge branch via a change in the adjustable impedance.

In this way, an idle value or an initial value of the switching strip system can be set in a simple manner to a predefined value. This value may be zero, but in practice a non-zero value is selected. The switching strip system can thus be set to a predefined voltage difference in the installed condition by means of the adjustable impedance. This is of considerable importance if the switching strip system according to the invention is installed as a series product. It is totally inevitable that the installation conditions of the switching strip system, for example on a motor-operated tailgate of a vehicle, are not always exactly identical. An automatic equalization can then be performed via the adjustable impedance immediately after the installation of the switching strip system. This can even be done, for example, on the assembly line during the manufacture of motor vehicles. The same voltage value can thereby always be fed to the electronic evaluation unit in the idle condition, i.e. without an obstacle. The adjustable impedance may be formed, for example with one or more capacitance diodes in a parallel and/or series circuit which are then connected by means of an, in particular automatic, control so that the desired value of the adjustable impedance is achieved. The use of a capacitor array which is correspondingly controlled or a variable capacitor is also possible.

In one development of the invention, the electronic evaluation unit has an adjustable impedance in order to effect an equalization of the output signal of the electronic evaluation unit.

The adjustable impedance may be provided in the electronic evaluation unit itself, and the adjustable impedance is advantageously provided in the feedback branch of an amplifier of the electronic evaluation unit.

In one development of the invention, a voltage level of the control signal amounts to twice to fifteen times, in particular ten times, the supply voltage of the electronic evaluation unit.

In this way, the sensitivity of the switching strip system to electromagnetic interference can be further reduced. Due to the high voltage level of the control signal, the voltage deviation caused by the approach of an obstacle is significantly higher than the influence of electromagnetic interference, so that the reliability of a detection of obstacles can be increased.

In one development of the invention, the control signal is designed as a sinusoidal signal. This sinusoidal signal advantageously has a voltage deviation of between 20 V and 40 V, in particular 30 V.

The control circuit advantageously has an oscillating circuit with which the control signal designed as a sinusoidal signal can be generated.

In one development of the invention, the sum of the impedances of the oscillating circuit is less than the sum of the impedances of the bridge circuit which are connected to the first end of the bridge branch. As a result, the oscillating circuit has a lower-impedance connection and the control signal itself is not influenced by the approach of an obstacle.

In one development of the invention, the oscillating circuit is partially formed by the impedances of the bridge circuit which are connected to the first end of the bridge branch. Due to such a partial integration of the oscillating circuit into the bridge circuit, the sum of the impedances of the bridge circuit which are connected to the first end of the bridge branch and therefore to the conductor of the switching strip profile positioned upstream in the direction of detection can be designed as having a lower impedance. The range of the detection of obstacles can thereby be improved with the switching strip system according to the invention.

In one development of the invention, the electronic evaluation unit has a differentiator, wherein input signals of the differentiator are weighted differently in order to effect an equalization of the output signal of the electronic evaluation unit.

An automatic equalization of the switching strip system according to the invention can also be performed by means of different weighting of the input signals of a differentiator, so that, for example, slightly different installation conditions in series production can be automatically compensated.

In one development of the invention, the electronic evaluation unit has a microcontroller, wherein the microcontroller is connected directly to the first end and the second end of the bridge branch.

An automatic equalization of the voltage difference to a predefined value can also be performed by means of a microcontroller in order to be able to compensate automatically for any different installation conditions in series production.

The problem on which the invention is based is also solved by a method for the capacitive detection of obstacles with a sensor system according to the invention in which the evaluation of a voltage difference between the first end and the second end of the bridge branch is provided.

Further features and advantages of the invention can be found in the claims and in the following description of preferred embodiments of the invention in conjunction with the drawings. Individual features of the different embodiments that are shown and described can be combined in any given manner without exceeding the scope of the invention. In the drawings:

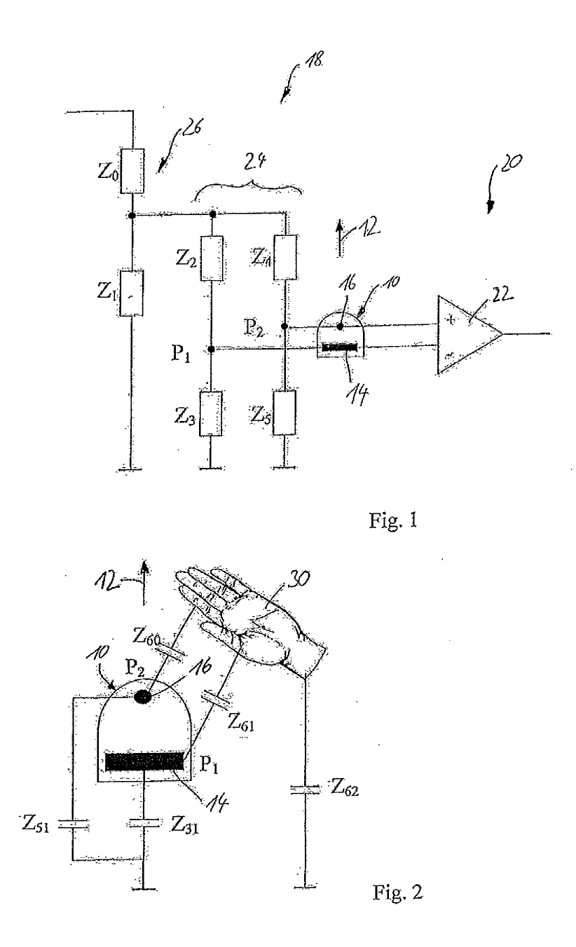

FIG. 1 shows a schematic diagram of a switching strip system according to the invention according to a first embodiment,

FIG. 2 shows a schematic representation to explain the measurement principle of the switching strip system according to the invention,

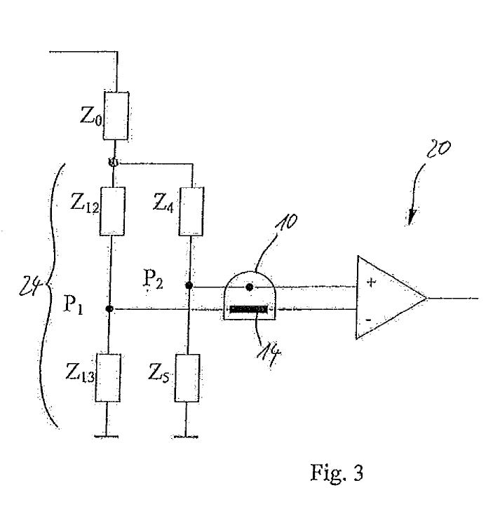

FIG. 3 shows a schematic diagram of a second embodiment of the switching strip system according to the invention,

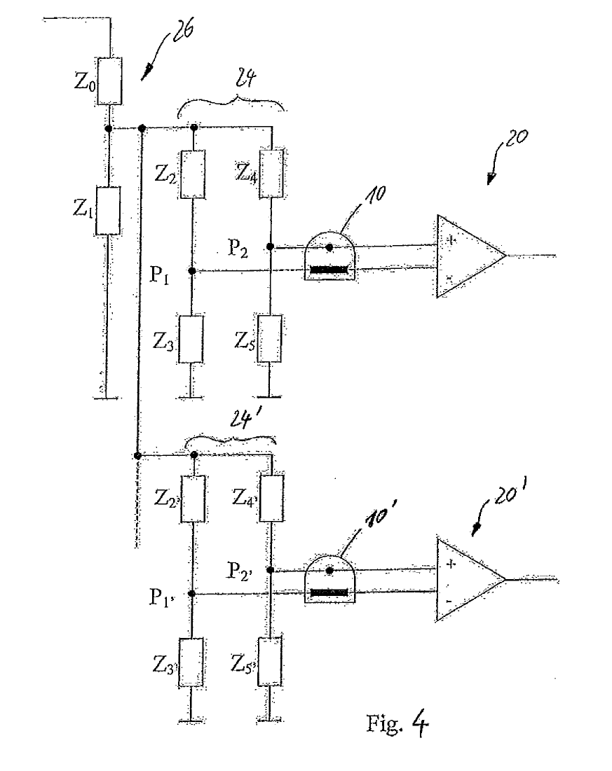

FIG. 4 shows a schematic diagram of a third embodiment of the switching strip system according to the invention,

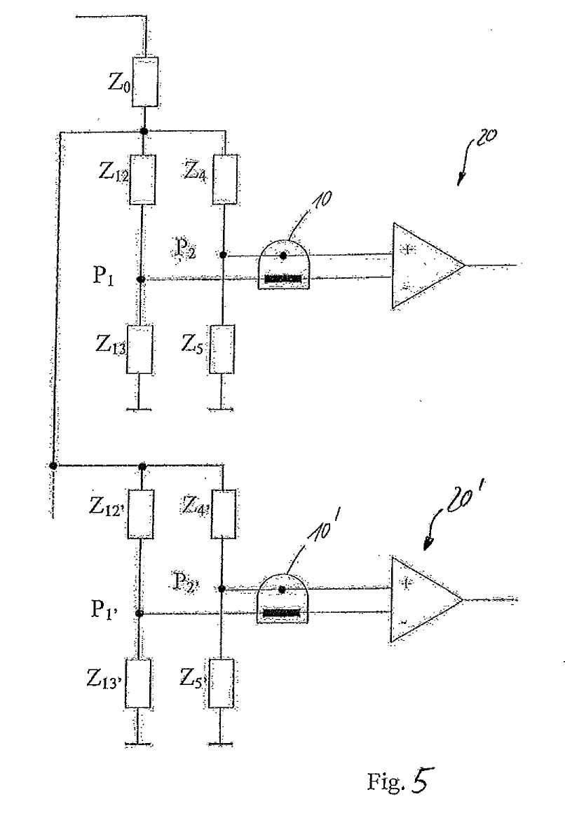

FIG. 5 shows a schematic diagram of a fourth embodiment of the switching strip system according to the invention,

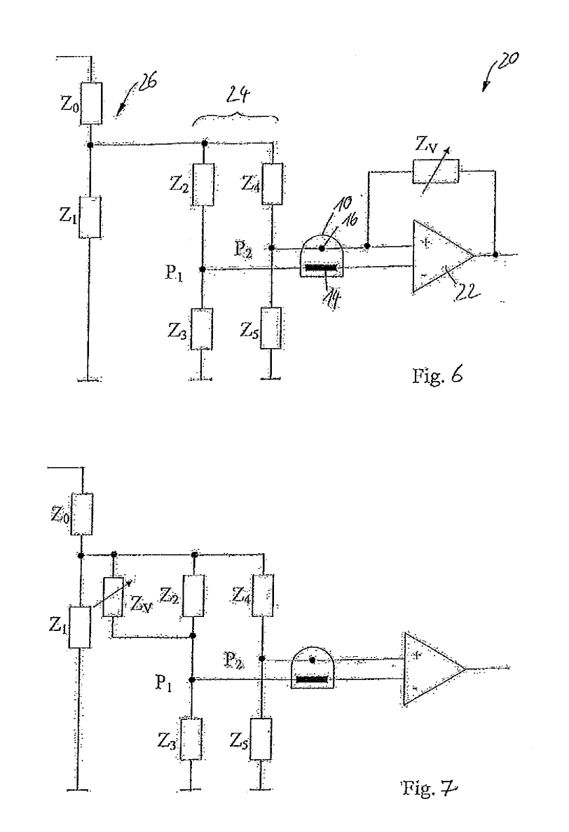

FIG. 6 shows a schematic diagram of a fifth embodiment of the switching strip system according to the invention,

FIG. 7 shows a schematic diagram of a sixth embodiment of the switching strip system according to the invention,

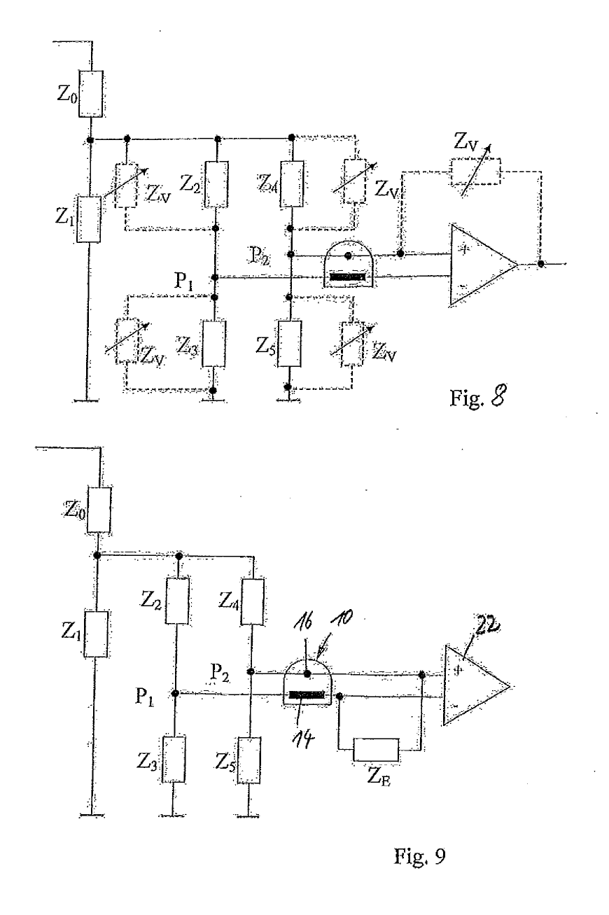

FIG. 8 shows a schematic diagram of a seventh embodiment of the switching strip system according to the invention, wherein different possible positions of one or more adjustable impedances are shown by dotted lines, and

FIG. 9 shows a schematic diagram of an eighth embodiment of the switching strip system according to the invention.

The representation in FIG. 1 shows a schematic diagram of a switching strip system or sensor system according to the invention according to a first embodiment. A switching strip profile 10 has a conductor 14 positioned upstream, as seen in a direction of detection 12, and a conductor 16 positioned downstream, as seen in the direction of detection 12. The direction of detection 12 merely represents the midline of a detection area which may extend over a greater angular range. The two conductors 16, 14 are merely shown schematically and may have a different geometric shape than the geometric shape illustrated. For the sake of simplicity, only two conductors 14, 16 are shown. The switching strip profile 10 may have more than two conductors according to the invention, for example a conductor 14 positioned upstream in the direction of detection 12, and three conductors 16 positioned downstream in the direction of detection 12. According to the invention, a capacitive sensor with at least two conductive elements can generally also be provided, for example an area sensor.

The switching strip system has a control circuit with a control section 18 and an electronic evaluation unit 20. In the schematic diagram shown in FIG. 1, the evaluation unit 20 is presented in the form of a single operational amplifier 22, but may obviously have a plurality of amplifiers, microcontrollers or the like, provided that they are capable of evaluating a voltage difference between the first conductor 14 and the second conductor 16.

The control section 18 has a bridge circuit 24 with four impedances Z₂, Z₃, Z₄ and Z₅. A bridge branch is defined between the points P₁ and P₂ and the conductor 14 of the switching strip profile 10 positioned upstream in the direction of detection 12 is connected to the first end P₁ of the bridge branch and the conductor 16 of the switching strip profile 10 positioned downstream in the direction of detection 12 is connected to the second end P₂ of the bridge branch. The two impedances Z₂ and Z₃ are connected to the first end P₁ of the bridge branch. Z₃ connects the first end P₁ to ground. Z₂ connects the first end P₁ of the bridge branch to an oscillating circuit 26.

The second end P₂ of the bridge branch is connected to the impedances Z₄ and Z₅. Z₅ connects the second end P₂ of the bridge branch to ground. Z₄ connects the second end P₂ of the bridge branch to the oscillating circuit 26.

The oscillating circuit 26 has a first impedance Z₀ and a second impedance Z₁. The impedances Z₂ and Z₄ are connected to a point between the two impedances Z₀ and Z₁. Z₁ is connected, on the other side, to ground. The representation of the oscillating circuit 26 is merely schematic, the oscillating circuit 26 being excited in such a way that a sinusoidal signal is formed at the point between the impedances Z₀ and Z₁.

The sum of the impedances Z₀ and Z₁ which form the impedance of the oscillating circuit 26 is less than the sum of the second impedance Z₂ and the third impedance Z₃. The sum of the impedances Z₂ and Z₃ is in turn less than the sum of the fourth impedance Z₄ and the fifth impedance Z₅.

The impedances Z₂, Z₃, Z₄ and Z₅ are selected in such a way that a desired voltage level is present in each case on the upstream conductor 14 and the downstream conductor 16. In the operation of the switching strip system, a sinusoidal signal is thus present on both conductors 14, 16, wherein the voltage amplitudes and the voltage levels of these sinusoidal signals may be different, but, depending on the intended purpose of the application, may also be identical.

The two inputs of the operational amplifier 22 or generally the two inputs of the electronic evaluation unit 20 are connected to the first end P₁ of the bridge branch or the second end P₂ of the bridge branch and therefore also to the upstream conductor(s) 14 or the downstream conductor(s) 16. The operational amplifier 22 or the electronic evaluation unit 20 thus evaluates a voltage difference between the first end P₁ of the bridge branch and the second end P₂ of the bridge branch and, concomitantly, the voltage difference between the two conductors 14, 16.

In the idle state, i.e. when no obstacle is located downstream of the switching strip profile 10, seen in the direction of detection 12, the electronic evaluation unit 20 recognizes a constant voltage difference between the two conductors 14, 16. If an obstacle then approaches the switching strip profile 10, the capacitances between the upstream conductor 14 and ground and between the downstream conductor 16 and ground change. The reason for this is that an obstacle, for example a human hand, forms a capacitance between itself and each of the two conductors 14, 16 and additionally also a capacitance between itself and ground. The approach of an obstacle will therefore also change the signal on the two conductors 14, 16. Since the sum of the capacitances Z₂ and Z₃ differs from the sum of the capacitances Z₄ and Z₅, the approach of an obstacle will influence the signal on the upstream conductor 14 differently than the signal on the downstream conductor 16. A voltage difference will thus form between the first end P₁ and the second end P₂ of the bridge branch and can be detected by means of the electronic evaluation unit 20 and evaluated so that an obstacle is detected if a predefined limit value is exceeded. Following the detection of an obstacle, the drive of an electrically driven tailgate, for example, can be stopped or reversed.

The representation in FIG. 1 clearly shows that the approach of an obstacle influences both the signal on the upstream conductor 14 and the signal on the downstream conductor 16. The evaluation of the voltage difference between the upstream conductor 14 and the downstream conductor 16 and between the first end P₁ and the second end P₂ of the bridge branch thus has the fundamental disadvantage that the approach of an obstacle is partially compensated. Surprisingly, however, the evaluation of the voltage difference between the first end P₁ and the second end P₂ of the bridge branch has the substantial advantage that interfering influences on the two conductors 14, 16 are also automatically compensated. If, for example, the switching strip 10 is located in the field of an electromagnetic radiation, both conductors 14, 16 are hereby influenced and the signal on the two conductors 14, 16 will therefore also reflect the influence of this electromagnetic interference. However, this electromagnetic interference is automatically eliminated in the determination of the difference between the voltages on the two conductors 14, 16. The same applies, for example, to interference due to temperature influence, for example if the switching strip 10 changes its temperature. As a result, the resistances of the conductors 14, 16 and, where relevant, also a capacitance between the two conductors 14, 16 and, where relevant, also a capacitance of the two conductors 14, 16 to ground will also inevitably change. However, in such a case also, the signals on the two conductors 14, 16 will be influenced so that these interfering influences will be eliminated by the evaluation of the voltage difference between the first end P₁ and the second end P₂ of the bridge branch. The fundamental disadvantage in the evaluation of the voltage difference between the two conductors 14, 16 will therefore be more than compensated by the substantial advantage of a very low sensitivity to interference.

The representation in FIG. 2 serves to explain the measurement principle with the switching strip system according to the invention, wherein the measuring circuit itself is not shown in the drawing for the sake of clarity. The two conductors 14, 16 of the switching strip profile 10 in each case form a capacitance to ground. A capacitance between the conductor 14 positioned upstream, seen in the direction of detection 12, is denoted Z₃₁, a capacitance between the conductor 16 positioned downstream in the direction of detection 12 and ground is denoted Z₅₁. A hand 30 forms an obstacle to be detected by means of the switching strip system. The hand 30 has a capacitance to ground Z₆₂, representing the human body with its discharge to ground. The hand 30 forms a capacitance Z₆₀ with the conductor 16 positioned downstream in the direction of detection 12 and a capacitance Z₆₁ with the conductor 14 positioned upstream in the direction of detection 12. The voltage signals on both conductors 14, 16 are thus influenced by the hand 30. As a result of the presence of the hand 30, the voltages on the first end P₁ of the bridge branch and on the second end P₂ of the bridge branch thus change in the same direction, but with different strengths, since, as explained, the impedances Z₂ and Z₃ are different from Z₄ and Z₅. This results in a voltage difference which can then be evaluated. A dimensioning of the impedances Z₂, Z₃, Z₄ and Z₅, see FIG. 1, in such a way that the ratio

$$\frac{{Z}_{61}}{{Z}_{60}}$$

is equal to the ratio of the sum of the impedances in the first and the second bridge branch, i.e.

$$\frac{{Z}_{61}}{{Z}_{60}} = \frac{{Z}_{2} + {Z}_{3}}{{Z}_{4} + {Z}_{5}}$$

has been found to be advantageous.

The aim is that, as far as possible, no phase shift occurs in the input signals on the inputs of the operational amplifier 22.

The representation in FIG. 3 shows a schematic diagram of a switching strip system according to the invention according to a further embodiment of the invention. Only the features differing from the embodiment shown in FIG. 1 will be explained.

In the embodiment shown in FIG. 3, an oscillating circuit is integrated into the bridge circuit 24. The oscillating circuit is formed by the impedances Z₀, Z₁₂ and Z₁₃. The first end P₁ of the bridge branch is located between the impedances Z₁₂ and Z₁₃. The impedance Z₄ is connected to a point between the impedances Z₀ and Z₁₂. Through the integration of the oscillating circuit into the branch of the bridge circuit which is connected to the first end P₁ of the bridge circuit, this side of the bridge circuit can be designed as having a lower impedance. The impedance Z₁₃ can therefore be selected as less than the impedance Z₃ according to FIG. 1.

When an obstacle approaches, see FIG. 2, the impedance Z₁₃ is located parallel to the capacitance Z₃₁, since both the impedance Z₁₃ and the capacitance Z₃₁ connect the conductor 14 located upstream in the direction of detection and the first end P₁ of the bridge branch to ground. However, compared with the embodiment shown in FIG. 1, the impedance formed by the parallel connection of the impedances Z₁₃ and Z₃₁ is less than the sum of the impedances Z₆₁ and Z₆₂, see FIG. 2. The impedances Z₆₁ and Z₆₂ represent the capacitance of the hand 30 to the upstream conductor 14 and between the hand 30 and ground. As a result, the switching strip system reacts more sensitively to the approach of a hand 30 and the range can be optimized.

The representation in FIG. 4 shows a further embodiment of a switching strip system according to the invention. The switching strip system shown in FIG. 4 has a first switching strip profile 10 and a second switching strip profile 10 ′. Further switching strip profiles can be connected in the same way. An electronic evaluation unit 20 or 20 ′ is allocated to each switching strip profile 10, 10 ′. A bridge circuit 24 or 24 ′ is also allocated to each switching strip profile 10, 10 ′. The oscillating circuit 26 feeds the generated sinusoidal signal not only into the bridge circuit 24 and therefore into the conductors of the switching strip profile 10 but also into the bridge circuit 24 ′ and therefore into the conductors of the switching strip profile 10 ′. In this way, two or more switching strip profiles 10, 10 ′ can be controlled with the same sinusoidal signal. For example, switching strips on different sides of a motor-driven tailgate can be controlled and evaluated in this way.

The representation in FIG. 5 shows a further embodiment of a switching strip system according to the invention. In this embodiment also, two or more switching strips 10, 10 ′ or a plurality of sensors are provided and each of these switching strips 10, 10 ′ or sensors is allocated to the electronic evaluation unit 20 or 20 ′. As in the embodiment explained with reference to FIG. 3, the oscillating circuit is integrated into the side of the bridge circuit which is connected to the first end P₁ or P_{1′}of the bridge branch. For example, two switching strips 10, 10 ′ can be combined with one or more capacitive area sensors.

FIG. 6 shows a further embodiment of a switching strip system according to the invention, wherein, compared with the switching strip system shown in FIG. 1, only one adjustable impedance Z_{V} is provided. The adjustable impedance Z_{V}, is provided in the feedback branch of the operational amplifier 22. The voltage difference between the two conductors 14, 16 and the voltage difference between the first end P₁ and the second end P₂ of the bridge branch can be set to a desired value with the adjustable impedance Z_{V}. As a result, for example, slightly different installation conditions in series production can be compensated, and the same voltage difference is always present on the operational amplifier 22 or on the electronic evaluation unit in the idle state, i.e. without the presence of an obstacle. The adjustable impedance Z_{V} is advantageously set immediately after the installation of the switching strip profile 10 and the switching strip system is thereby equalized. This can take place, for example, during production on the assembly line, for example when the switching strip profile 10 has been fitted in the area of the tailgate of a motor vehicle.

The representation in FIG. 7 shows a further switching strip system according to the invention, wherein, unlike in the representation in FIG. 6, the adjustable impedance Z_{V} has now been provided in parallel with the impedance Z₂ which connects the first end P₁ of the bridge branch to the point between the impedances Z₀ and Z₁. Such an arrangement of the adjustable impedance Z_{V} also allows an, in particular automatic, equalization of the voltage difference between the first end P₁ and the second end P₂ of the bridge branch.

The representation in FIG. 8 shows the switching strip system from FIG. 1, wherein possible positions of the adjustable impedance Z_{V} are indicated by dotted lines. Each of these positions of the adjustable impedance Z_{V}, indicated by dotted lines can be selected alone, but two or more adjustable impedances Z_{V} are possible at the positions shown in order to provide an automatic equalization of the voltage difference between the first end P₁ and the second end P₂ of the bridge branch.

The representation in FIG. 9 shows a further sensor system according to the invention, wherein a further impedance Z_{E} which interconnects the two conductors 14, 16 of the switching strip 10 is provided between the operational amplifier 22 and the two conductors 14, 16 of the switching strip 10. The impedance Z_{E} is designed as an inductance and is appropriately provided at one end of the switching strip 10. The circuit can be made very narrowband by means of the impedance Z_{E}, as a result of which a very high sensitivity is achieved in the area of the resonant frequency. In addition, the impedance Z_{E} can be used for the diagnosis of the switching strip 10, i.e. to check whether the conductors 16 of the switching strip 10 are interrupted or short-circuited.

1. A sensor system for the capacitive detection of obstacles, having a capacitive sensor with at least two conductive elements and a control circuit connected to the conductive elements, wherein the control circuit has a bridge circuit, wherein a first end of the bridge branch is connected to a conductive element of the sensor positioned upstream in the direction of detection and a second end of the bridge branch is connected to a conductive element of the sensor positioned downstream in the direction of detection, wherein a control signal is generated by a control section of the control circuit and wherein the sum of the impedances of the bridge circuit which are connected to the first end of the bridge branch is less than the sum of the impedances of the bridge circuit which are connected to the second end of the bridge branch, wherein the control signal is fed into both conductive elements and an electronic evaluation unit is provided to evaluate a voltage difference between the first end and the second end of the bridge branch.

2. The sensor system as claimed in claim 1, wherein that the two conductive elements are designed as conductors running continuously in the longitudinal direction of a switching strip profile or as flat electrodes or grid electrodes of a capacitive area sensor.

3. The sensor system as claimed in claim 1, wherein the control section has a first impedance, wherein the first end of the bridge branch is disposed between a second and a third impedance and the second end of the bridge branch is disposed between a fourth and a fifth impedance, wherein the first impedance is less than the sum of the second and the third impedance and the sum of the second and the third impedance is less than the sum of the fourth and the fifth impedance.

4. The sensor system as claimed in claim 1, wherein an adjustable impedance is provided in parallel with at least one of the impedances of the bridge circuit in order to effect an equalization of the voltage difference between the first end and the second end of the bridge branch via a change in the adjustable impedance.

5. The sensor system as claimed in claim 1, wherein the electronic evaluation unit has an adjustable impedance in order to effect an equalization of the output signal of the electronic evaluation unit.

6. The sensor system as claimed in claim 5, wherein adjustable impedance is provided in the feedback branch of an amplifier of the electronic evaluation unit,

7. The sensor system as claimed in claim 1, wherein a voltage level of the control signal amounts to twice to fifteen times, in particular ten times, the supply voltage of the electronic evaluation unit.

8. The sensor system as claimed in claim 1, wherein the control signal is designed as a sinusoidal signal.

9. The sensor system as claimed in claim 1, wherein a voltage deviation of between 20 volts and 40 volts, in particular 30 volts.

10. The sensor system as claimed in claim 8, wherein the control circuit has an oscillating circuit.

11. The sensor system as claimed in claim 10, wherein the sum of the impedances of the oscillating circuit is less than the sum of the impedances of the bridge circuit which are connected to the first end of the bridge branch.

12. The sensor system as claimed in claim 10, wherein the oscillating circuit is partially formed by the impedances of the bridge circuit which are connected to the first end of the bridge branch.

13. A method for the capacitive detection of obstacles with a sensor system as claimed in claim 1, the method including evaluation of a voltage difference between the first end and the second end of the bridge branch.
